(19) United States
(12) Patent Application Publication
(10) Pub. No.: US 2002/0145481 A1
(43) Pub. Date: Oct. 10, 2002

(54) Method and apparatus to electronically enhance the tank quality factor of tank circuits and oscillators having tank circuits

(76) Inventor: Mihai Horia Murgulescu, San Jose, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/793,934

(22) Filed: Feb. 27, 2001

(51) Int. Cl. H03B 5/12

(52) U.S. Cl. 331/117 R; 331/167

(57) ABSTRACT

Methods and apparatus to control and enhance the quality factor of a tank circuit and oscillators having a tank circuit by feeding back a voltage to the tank circuit in opposition to the losses in the tank circuit. In an exemplary embodiment, a degenerate common emitter stage, responsive to the voltage across a differential circuit, has magnetically coupled inductors coupling voltages back to a differential tank in opposition to the IR voltage losses in the differential tank circuit. The amount of feedback may be controlled by the bias on the common emitter stage. Various embodiments are disclosed.

### BACKGROUND OF THE INVENTION

1. Field of the Invention

The present invention relates to tank circuits and oscillators, such as voltage controlled oscillators utilizing tank circuits.

2. Prior Art

Tank circuits are used in various devices, including oscillators such as voltage controlled oscillators. The quality factor (Q) of the tank circuit generally affects the performance of the tank circuit, the higher the Q the better the tank circuit normally performs for its intended function. In the case of tank circuits used in monolithic oscillators, the Q achievable in practical designs is quite limited, giving rise to phase noise in the oscillator which can limit the performance of the circuit in which the oscillator is used. Since monolithic (integrated circuit) oscillators, such as voltage controlled oscillators, are widely used in communications equipment, as well as other applications wherein low phase noise is required, some method of enhancing the Q of such tank circuits is desired. The present invention provides such enhancement, though its use is not so limited, having the capability of controlling the amplitude of a tank circuit oscillation through control of the Q of the tank circuit when desired.

### BRIEF SUMMARY OF THE INVENTION

Methods and apparatus to control and enhance the quality factor of a tank circuit and oscillators having a tank circuit by feeding back a voltage to the tank circuit in opposition to the losses in the tank circuit. In an exemplary embodiment, a degenerate common emitter stage, responsive to the voltage across a differential circuit, has magnetically coupled inductors coupling voltages back to a differential tank in opposition to the IR voltage losses in the differential tank circuit. The amount of feedback may be controlled by the bias on the common emitter stage. Various embodiments are disclosed.

### BRIEF DESCRIPTION OF THE DRAWINGS

FIG. 1 is a circuit schematic of a preferred embodiment of the present invention.

### DETAILED DESCRIPTION OF THE PREFERRED EMBODIMENT

In order to convey the concepts of the present invention, the same will be described with respect to a specific implementation. Such implementation is exemplary only and is provided for purposes of communication and not by way of limitation.

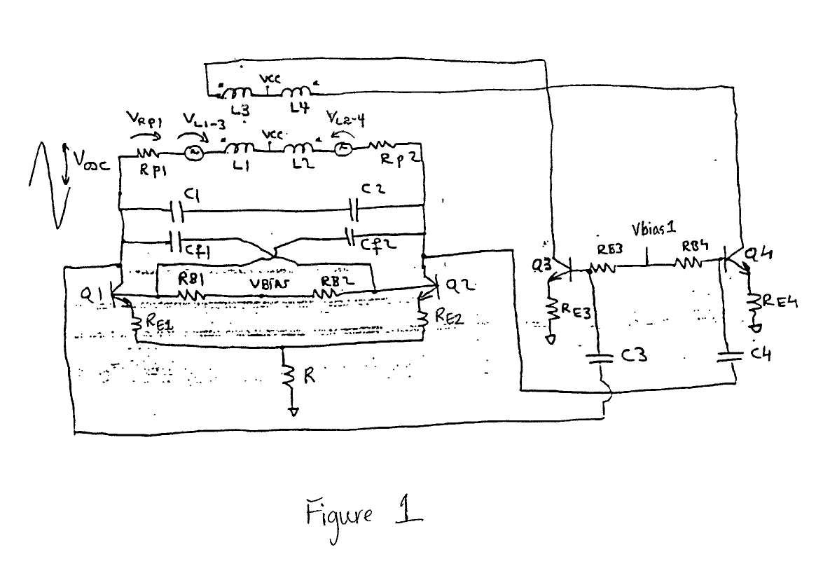

Thus, for purposes of explanation and not by way of limitation, an exemplary embodiment of the present invention is shown in FIG. 1. As shown in that Figure, a classical capacitively cross-coupled voltage controlled oscillator core is created by transistors Q1 and Q2, with the monolithic tank consisting of the inductors L1 and L2 and capacitors C1 and C2. The voltage controlled oscillator core feedback to maintain oscillation is ensured by capacitors CF1 and CF2. Q1 and Q2 are appropriately biased by resistors RB1 and RB2, respectively, through a bias voltage source Vbias, with resistors RE1 and RE2 providing emitter degeneration for transistors Q1 and Q2, respectively. Resistors RE1 and RE2 are coupled to the circuit ground through resistor R acting as a current source for the common connection of resistors RE1 and RE2.

The tank circuit as drawn in FIG. 1 includes resistors Rp1 and Rp2 as well as voltage sources V_{L1-3} and V_{L2-4} in series with the inductors L1 and L2. The resistors Rp1 and Rp2 represent the lumped resistance in the tank which limit the Q of the tank, particularly in a monolithic tank. The voltages V_{L1-3} and V_{L2-4} are equivalent circuit representations of the voltages induced in the tank circuit from magnetic coupling between inductors L3 and L4 and inductors L1 and L2, respectively, in accordance with the present invention. In particular, the present invention includes an added feedback loop which feeds back voltages to the voltage controlled oscillator core proportional to, and in phase opposition with, voltages VRP1 and VRP2, representing the resistive loss elements in the tank, thereby reducing the effect of losses in the tank and enhancing the Q thereof.

The added feedback loop is a degenerate common emitter stage comprising transistors Q3 and Q4 biased through resistors RB3 and RB4 from a bias voltage source Vbias, which may be the same as or different from the bias Vbias of the tank circuit. Resistors RE3 and RE4 provide emitter degeneration for the transistors Q3 and Q4. The oscillation voltage of the tank circuit V_{OSC} is coupled to the bases of transistors Q3 and Q4 through capacitors C3 and C4, which have a low impedance at the oscillation frequency compared to the input impedance of the degenerate common emitter stage. The collector loads for transistors Q3 and Q4 are inductors L3 and L4, respectively, which are strongly magnetically coupled to inductors L1 and L2 with a negative coupling coefficient. The impedance of inductors L3 and L4 at the oscillation frequency is low compared to the impedance looking into the collector of transistors Q3 and Q4 so that the transistors act as transconductors with very little phase shift between their base input voltages and their collector output currents. This coupling creates apparent negative resistances in series with the resistors Rp1 and Rp2, respectively, reducing the effect of these resistances to enhance the Q of the tank.

In the circuit shown in FIG. 1, the voltage across resistor Rp1 is:

$${V}_{Rp1} = \frac{{V}_{OSC}}{j ω {L}_{1}} {R}_{p1}$$

where:

V_{OSC}=the oscillation amplitude on the collector of transistor Q1

ω=the oscillation frequency in radians per second

L1=the inductance of L1

Rp1=the effective resistance of the tank circuit

The voltage V_{L1-3} magnetically injected in series with inductor L1 by the magnetic coupling from inductor L3 is:

$${V}_{L1 - 3} = {V}_{OSC} \frac{- {g}_{m3}}{1 + {g}_{m3} {R}_{e3}} j ω {M}_{13}$$

where:

gm3=the transconductance of transistor Q1

M₁₃=the coupling coefficient between inductor

L1 and inductor L3

It can be seen from the foregoing equations that by choosing proper polarities, the voltages magnetically injected into the tank circuit by the coupling between inductors L1 and L3 and L2 and L4 are proportional to and in phase opposition with the voltages across the lumped resistances Rp1 and Rp2. Therefore the voltages V_{L1-3} and V_{L2-4} generated by the feedback coupling may be considered to create negative resistances in series with resistances in the tank circuit, which increases the equivalent tank Q, increasing the oscillation voltage and reducing the phase noise in the tank circuit. This feedback itself has a limited effect on the oscillation frequency of the tank circuit, as the resonant frequency of a tank circuit is relatively independent of the Q of the circuit, at least for tank circuits having a substantial Q.

The amount of the negative resistance created by the feedback, and thus the amount of Q enhancement of the tank circuit, can be controlled by adjusting the DC bias current in transistors Q3 and Q4, such as by way of example, by adjusting the bias voltage Vbias1 used to bias the bases of the transistors Q3 and Q4 by a one-time component trimming during the integrated circuit fabrication. Alternatively, in some applications it may be desired to provide a variable Q for the tank circuit, in which case the bias for transistors Q3 and Q4 might purposely be made a controllable variable for that purpose.

The present invention has been described with respect to use in an oscillator, though may be readily applied to tank circuits of other configurations and in other devices as desired. Thus while a preferred embodiment of the present invention has been disclosed and described in detail herein, it will be obvious to those skilled in the art that various changes in the form and detail may be made with out departing from the spirit and scope of the invention.

What is claimed is:

1. A method of improving the quality factor of a monolithic tank circuit having a first inductor comprising:
providing as part of the monolithic circuit, a second inductor magnetically coupled to the first inductor;
providing as part of the monolithic circuit, a current through the second inductor which is substantially inphase with the voltage across the tank and in an amount and polarity to induce a voltage in the tank circuit equal to a fraction of the voltage drop from the resistance in the tank circuit and in opposition thereto.

2. The method of claim 1 wherein the current through the second inductor is provided by a degenerate common emitter stage.

3. The method of claim 2 wherein the degenerate common emitter stage is responsive to the voltage across the tank circuit.

4. A method of improving the quality factor of a monolithic tank circuit in a voltage controlled oscillator having a first inductor comprising:
providing as part of the monolithic circuit, a second inductor magnetically coupled to the first inductor;
providing as part of the monolithic circuit, a current through the second inductor which is substantially inphase with the voltage across the tank and in an amount and polarity to induce a voltage in the tank circuit equal to a fraction of the voltage drop from the resistance in the tank circuit and in opposition thereto.

5. The method of claim 4 wherein the current through the second inductor is provided by a degenerate common emitter stage.

6. The method of claim 5 wherein the degenerate common emitter stage is responsive to the voltage across the tank circuit.

7. A voltage controlled oscillator comprising:
in a single monolithic circuit:
a capacitively cross-coupled voltage controlled oscillator core having a tank circuit including first and second inductors;
third and fourth inductors magnetically coupled to the first and second inductors, respectively;
a circuit responsive to the voltage across the tank circuit providing currents through the third and fourth inductors, respectively, which are substantially inphase with the voltage across the tank and in an amount and polarity to induce a voltage in series with the first and second inductors, respectively, equal to a fraction of the voltage drop from the resistance in the tank circuit and in opposition thereto.

8. The voltage controlled oscillator of claim 7 wherein the circuit responsive to the voltage across the tank circuit is a degenerate common emitter stage.

9. The voltage controlled oscillator of claim 8 wherein the degenerate common emitter stage is responsive to the voltage across the tank circuit.

10. In an integrated circuit:
a first circuit including a tank circuit having an inductor;
a second inductor magnetically coupled to the first inductor;
a second circuit responsive to the voltage across the tank circuit providing a currents through the second inductor which is substantially inphase with the voltage across the tank and in an amount and polarity to induce a voltage in series with the first inductor equal to a fraction of the voltage drop from the resistance in the tank circuit and in opposition thereto.

11. The integrated circuit of claim 10 wherein the second circuit is a degenerate common emitter stage.

12. The integrated circuit of claim 11 wherein the degenerate common emitter stage is responsive to the voltage across the tank circuit.
